(19) United States
(12) Patent Application Publication
(10) Pub. No.: US 2005/0061363 A1
(43) Pub. Date: Mar. 24, 2005

(54) Organic solar cells including group IV nanocrystals and method of manufacture

(76) Inventors: David S. Ginley, Evergreen, CO (US); Jack I. Hanoka, Brookline, MA (US)

Correspondence Address: PROSKAUER ROSE LLP, ONE INTERNATIONAL PLACE 14TH FL, BOSTON, MA, 02110, US

(21) Appl. No.: 10/949,262

(22) Filed: Sep. 23, 2004

Related U.S. Application Data
(60) Provisional application No. 60/505,200, filed on Sep. 23, 2003.

(51) Int. Cl. H01L 31/00

(52) U.S. Cl. 136/252; 136/260

(57) ABSTRACT

An improved organic solar cell converts light into electricity. The organic solar cell includes a cathode, an anode, and a bulk heterojunction material disposed therebetween. The bulk heterojunction material includes a plurality of group IV nanocrystals (e.g., silicon nanocrystals) disposed within an organic absorber (e.g., an organic polymer).

### RELATED APPLICATIONS

This application claims the benefit of the filing date of U.S. Provisional Patent Application Ser. No. 60/505,200, filed on Sep. 23, 2003, entitled “A Method for Forming Organic Solar Cells using Nanocrystalline Silicon” by Ginley et al., the entirety of which is incorporated herein by reference.

### FIELD OF THE INVENTION

The invention generally relates to solar cells, and more particularly to organic solar cells, which include a mixture of an organic absorber and a plurality of group IV nanocrystals to form the bulk heterojunction material within the solar cell.

### BACKGROUND OF THE INVENTION

Organic solar cells (also called plastic, polymer, or excitonic solar cells) have recently attracted significant interest and represent an attractive possibility for making flexible solar electric panels that offer the potential for low cost solar electricity. In general, known organic solar cells include an organic material positioned between two electrodes. The organic material absorbs light and in response generates an exciton (i.e. a bound electron/hole pair). The organic solar cell also includes a heterojunction (i.e., a junction between two different materials) between electron-donating molecules (e.g., donor) and electron-accepting molecules (e.g., acceptor) to create a phase-separated large area interface. The hetrojunction serves to separate the excitons into electrons and holes. In some cases, the organic material serves as both the light absorber and the electron-donating molecule (i.e., donor) of the heterojunction. A number of different donor-acceptor combinations (i.e., heterojunction material) have been investigated for use within organic solar cells. Some of the heterojunction materials investigated include: an organic polymer (donor)—fullerene (acceptor), an organic polymer (donor)—perylene (acceptor), an organic polymer (donor)—nanorods of group II-IV compounds, such as nanorods of CdSe, (acceptor), an organic polymer (donor)—quantum-dot (acceptor), and an organ polymer (donor)—nanoparticles of CuInSe₂ (acceptor). The driving force in organic cells is believed to be a combination of the work function differential of the electrodes and a chemical gradient potential within the organic solar cell.

The design of the heterojunction between the donor and the acceptor species have generally taken two different forms: planar and bulk. In planar heterojunctions the two different materials forming the heterojunction create a single interface therebetween (e.g., a donor layer in contact with an acceptor layer). Bulk heterojunctions are formed by blending the donor and acceptor species together into a phase segregated mixture. Investigators have found that bulk heterojunction organic solar cell devices have a higher efficiency over planar heterojunction devices and thus, have focused more intently on bulk heterojunction materials. However the efficiency of known bulk heterojunction organic solar cell devices is less than 4%. In addition, these known organic solar cell devices have a small surface area in which the organic donor can absorb light (e.g., on the order of a few square millimeters). To give this some perspective, present day commercial crystalline silicon solar cells are about 13% to 20% efficient and have a much larger surface area in which light is absorbed (e.g., anywhere between about 100 to 225 square centimeters).

Some of the challenges with making efficient bulk heterojunction organic solar cells include the ability to form low resistance, low recombination contacts (the final contact will be an inorganic metal of some sort); the ability to efficiently absorb the full solar spectrum (many organic polymers absorbers cover only a portion of the solar spectrum); recombination of the holes and electrons that limit the thickness of the absorbing layer; and generally inefficient collection of the generated excitons before they recombine due to dimensions exceeding the 10 to 20 nm diffusion length of the excitons (the diffusion length of an exciton in a polymer is about 10 to 20 nm; this dimension establishes the scale needed in the microstructure of the solar cell to minimize recombination). These limitations mean that fill factors and short circuit currents are low for organic solar cells.

One method being investigated in an effort to decrease recombination of the excitons and thus increase cell efficiency is to create a large interfacial area between the donor and acceptor species within the bulk heterojunction material by using a nanostructured, porous inorganic material as an electron collecting cathode. The nanostructured porous inorganic material acts as scaffolding onto which the acceptors can attach. The organic polymer absorber is then intercalated into the porous volume of the scaffolding to complete the heterojunction material. Preferably, a conducting polymer, acting as an anode, can also be infiltrated into the porous structure. In such a device, excitons created by light absorption within the organic polymer absorber have a small distance to diffuse before reaching a donor-acceptor interface. As a result, the electron donated to the acceptor is injected into the cathode almost immediately, thereby decreasing the occurrence of recombination. The hole remaining in the organic absorber has a short distance to travel before reaching the anode.

A possible solution to the issue of forming low resistance and low recombination contacts is to use buffer layers within the organic solar cell. These buffer layers can provide different functions. For example, at an ITO interface (i.e., the anode interface), a buffer layer of PEDOT (poly(3,4-ethylenedioxythiophene) can increase the ITO work function and create a smoother electrode surface. At the cathode (i.e., aluminum layer), a buffer layer of bathocuproine (BCP) can be used to avoid recombination by only permitting the passage of electrons and/or a LiF buffer layer can be used to enhance the fill factor and to stabilize high open circuit voltages within the cell.

However, the issues of efficiency and light absorption from the full solar spectrum are still problematic for known organic solar cells. The organic polymers used as the photoactive material and the donor material do not absorb a significant amount of sunlight in the long wavelength region of the solar spectrum and thus limit the solar cell's efficiency. In fact, some researchers studying a heterojunction formed of poly(2-methoxy-5-(3′,7′-dimethyloctyloxy)-1,4-phenylene-vinylene), an organic polymer commonly referred to as MDMO-PPV, and PCBM, a fullerene derivative, have shown that light absorption of wavelengths of 600 nm and larger is particular low. Other researchers investigating poly (e-hexylthiophene), an organic polymer commonly referred to as P3HT, have found that incident light is absorbed mainly over the wavelength range of 450 nm to 600 nm (see FIG. 1) and have commented that known conjugated polymers have too large of an band gap energy to absorb a large fraction of the solar spectrum. In addition, due to concerns with recombination, the actual thickness of the organic polymer absorber must be very thin, on the order of about 100 to 150 nm. This further limits the amount of light that can be absorbed.

### SUMMARY OF THE INVENTION

In general, in one aspect, the present invention features an improved bulk heterojunction material for use within an organic solar cell. The bulk heterojunction material includes an organic absorber and a plurality of group IV nanocrystals disposed within the organic absorber. The organic absorber (e.g., polymer) absorbs sunlight having wavelengths between about 350 nm to about 650 nm and in response generates an exciton (i.e., a boound electron/hole pair). The group IV nanocrystals (e.g., silicon nanocrystals, germanium nanocrystals, silicon-germanium nanocrystals) act not only as acceptor molecules, but also provide the bulk heterojunction material with another source of absorption. The group IV nanocrystals absorb long wavelength sunlight (e.g. about 650 nm to 1000 nm), thereby increasing the absorption capability of the bulk heterojunction material.

Embodiments of this aspect of the invention can include one or more of the following features. The plurality of group IV nanocrystals comprises less than about 75 weight percent of the bulk heterojunction material (e.g., the bulk heterojunction material is formed of about 25 weight percent organic material and about 75 weight percent group IV nanocrystals, the bulk heterojunction material is formed of 30 weight percent organic material and 70 weight percent group IV nanocrystals, the bulk heterojunction material is formed of 50 weight percent organic material and 50 weight percent group IV nanocrystals). The group IV nanocrystals can include a variety of particle sizes, thereby enabling the bulk heterojunction material to absorb a range of wavelengths. The largest particle dimension of each of the plurality of group IV nanocrystals can be less than about 20 nanometers, and in some embodiments a portion of the plurality of the nanocrystals (e.g., some of the nanocrystals or all of the nanocrystals) can have a largest particle dimension within the range of about 2 nanometers to about 5 nanometers. A portion of the plurality of group IV nanocrystals can be doped. A portion of the plurality of group IV nanocrystals can be capped with a reagent, such as a reagent that prevents air and/or moisture oxidation or a reagent that increases wetting between the organic polymer and the group IV nanocrystals. Examples of reagents include alkyl lithium, grignards, alcohols, electroactive chelating agents, heterocyclic aromatic molecules, and dendrimer polymers. Organic absorbers used in the bulk heterojunction material include organic charge conductors, such as, for example, polymers, dendrimers, and macromers. Examples of some organic polymers include poly (e-hexylthiophene), poly-[2-methoxy, 5-(2′-ethyl-hexyloxy) phenylene vinylene], and poly(2-methoxy-5-(3′,7′-dimethyloctyloxy)-1,4-phenylene-vinylene).

In another aspect, the invention features a solar cell. The solar cell includes a cathode, an anode, and a bulk heterojuction material including a combination of an organic absorber and a plurality of group IV nanocrystals disposed between the cathode and the anode. At least one of the cathode and the anode is transparent (or at least semi-transparent) so that sunlight can pass therethrough and be absorbed by the bulk heterojunction material.

Embodiments of this aspect of the invention can include one or more of the following features. The plurality of group IV nanocrystals comprises less than about 75 weight percent of the bulk heterojunction material within the solar cell (e.g., the bulk heterojunction material is formed of about 25 weight percent organic material and about 75 weight percent group IV nanocrystals, the bulk heterojunction material is formed of 30 weight percent organic material and 70 weight percent group IV nanocrystals, the bulk heterojunction material is formed of 50 weight percent organic material and 50 weight percent group IV nanocrystals). The group IV nanocrystals can include a variety of particle sizes, thereby enabling the bulk heterojunction material to absorb a range of wavelengths. The largest particle dimension of each of the plurality of group IV nanocrystals can be less than about 20 nanometers, and in some embodiments a portion of the plurality of the nanocrystals can have a largest particle dimension within the range of about 2 nanometers to about 5 nanometers. A portion of the plurality of group IV nanocrystals can be doped. The group IV nanocrystals located near the cathode and the anode can be more heavily doped than the group IV nanocrystals located near the center of position of the solar cell. The bulk heterojunction material can include a heavily n-type doped region located near the cathode of the solar cell, a heavily p-type doped region located near the anode of the solar cell, and a light doped region located between the two heavily doped regions. A portion of the plurality of group IV nanocrystals in the bulk heterojunction material can be capped with a reagent, such as a reagent that prevents air and/or moisture oxidation or a reagent that increases wetting between the organic polymer and the group IV nanocrystals. Examples of reagents include alkyl lithium, grignards, alcohols, electroactive chelating agents, heterocyclic aromatic molecules, and dendrimer polymers. Organic absorbers used in the bulk heterojunction material include organic charge conductors, such as, for example, polymers, dendrimers, and macromers. Examples of some organic polymers include poly (e-hexylthiophene), poly-[2-methoxy, 5-(2′-ethyl-hexyloxy) phenylene vinylene], and poly(2-methoxy-5-(3′,7′-dimethyloctyloxy)-1,4-phenylene-vinylene).

In general, in another aspect, the invention features a method of forming a bulk heterjunction material. The method includes immersing a plurality of group IV nanocrystals (e.g. silicon nanocrystals, germanium nanocrystals, silicon-germanium nanocrystals) in an organic absorber. The bulk heterojunction material formed using the preceding method can be used within a solar cell. That is, a layer (e.g., a 75 nm to 200 nm thick layer) of the bulk heterojunction material can be deposited on a first electrode (e.g., an anode) and a second electrode (e.g., a cathode) can be positioned on top of the layer of bulk heterojunction material to form a solar cell.

Embodiments of this aspect of the invention can include one or more of the following features. The method can further include capping at least a portion of the plurality of the group IV nanocrystals with a reagent. The method can also include doping at least a portion of the plurality of the group IV nanocrystals. The group IV nanocrystal located near an electrode (e.g., a cathode, an anode) can be more heavily doped than group IV nanocrystals located near a center position of the solar cell. The regions of the bulk heterojunction material located near the electrodes can be more heavily doped than the center region of the bulk heterojunction material. The group IV nanocrystals used to form the bulk heterojunction material can include a variety of particle sizes so as to enable the bulk heterojunction material to absorb a range of wavelengths. For example, a portion of the plurality of the group IV nanocrystals can have a largest particle dimension within the range of about 2 nanometers to about 5 nanometers. Other group IV nanocrystals can have a largest particle dimension of about 20 nanometers or less.

In general, the bulk heterojunction material including both the organic absorber and the plurality of group IV nanocrystals as described above can include one or more of the following advantages. The bulk heterojunction material of the invention can absorb a broader spectrum of light in comparison to known organic bulk heterojunction materials, such as a combination of organic polymer and fullerenes. In particular, the group IV nanocrystals can act as both an absorber and an acceptor material. As a result, more light, including light having a longer wavelength (e.g., 650 nm to 1000 nm) can be absorbed by the bulk heterojunction material and thus greater solar cell efficiency can be achieved. Moreover, because the bulk heterojunction material is formed of a higher concentration of materials that can absorb light (i.e. both the organic absorber and the nanocrystals can absorb light in comparison to just the organic absorber in known organic heterojunction materials) more excitons can be generated. As a result, better collection at the electrodes and thus better solar cell efficiencies are possible. The bulk heterojunction material of the present invention is easy to manufacture and can be produced in high yield volumes. As a result, manufacturing expenses are reduced, which leads to a reduction in solar cell costs. In addition, the bulk heterojunction material is highly flexible and durable in comparison to single crystalline homojunction materials (e.g., doped silicon wafers). As a result, solar cells manufactured with the bulk heterojunction material of the present invention are less susceptible to damage and can be used in more demanding environments.

The foregoing and other aspects, features, and advantages of the invention will become more apparent from the following description and from the claims.

### BRIEF DESCRIPTION OF THE DRAWINGS

In the drawings, like reference characters generally refer to the same parts throughout the different views. Also, the drawings are not necessarily to scale, emphasis instead being placed upon illustrating the principles of the invention.

FIG. 1 is a graph showing the percentage of incident light absorbed by P3HT as a function of wavelength for a 40 nm thick layer of P3HT.

FIG. 2 is an illustration showing the visible region of the electromagnetic spectrum in terms of wavelength and corresponding energies.

FIG. 3 is an illustration of an organic solar cell in accordance with one embodiment of the invention.

FIG. 4 is a high resolution transmission electron microscope (HRTEM) image of a plurality of silicon nanocrystals.

FIG. 5 is a graph showing the distribution of size of the silicon nanocrystals of FIG. 4.

FIG. 6 is an illustration of an organic solar cell in accordance with another embodiment of the invention.

FIG. 7 is an illustration of an organic solar cell in accordance with another embodiment of the invention.

FIG. 8 is an illustration of an organic solar cell in accordance with another embodiment of the invention.

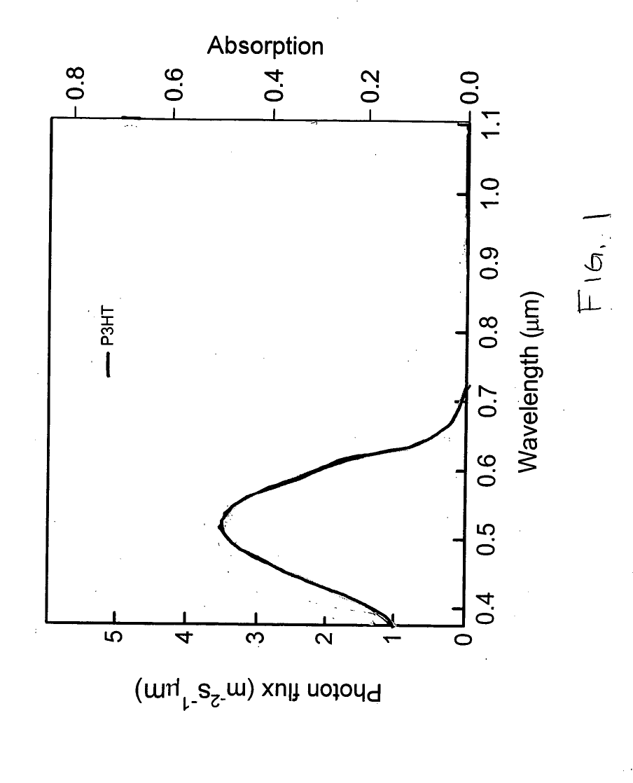

### DETAILED DESCRIPTION

The present invention provides an improved bulk heterojunction material for an organic solar cell and a method of making the bulk heterojunction material. In general, the bulk heterojunction material includes an organic absorber (e.g., an organic polymer) and a plurality of group IV nanocrystals (e.g., silicon nanocrystals, germanium nanocrystals, silicon-germanium nanocrystals) disposed within the organic absorber.

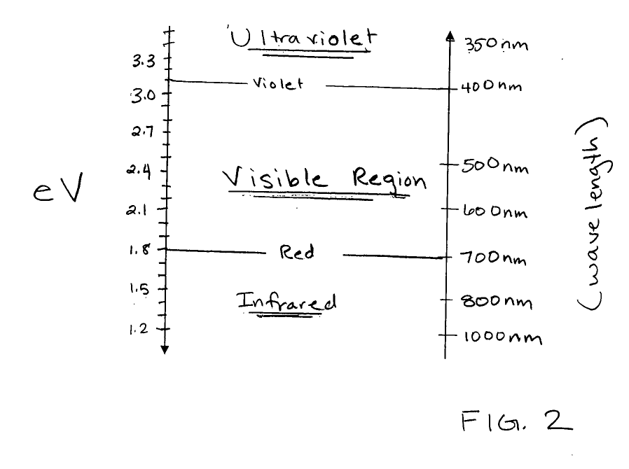

The organic absorber is a photoactive material that generates excitons (i.e., an electron/hole pair) in response to sunlight interaction. Typically, due to their band gap values (e.g., between about 1.9 eV to 3.5 eV), the organic absorber is most responsive to light having a wavelength between (350 nm and 650 nm). See FIG. 2, which shows the visible region of the electromagnetic spectrum in terms of wavelength and corresponding energies in eV. As a result, the organic absorber tends to generate excitons in response to sunlight having a wavelength between about 350 nm and 650 nm, and as a further result is an ineffective absorber of long wavelength sunlight (e.g., between about 650 nm and 1000 nm).

The group IV nanocrystals within the bulk heterojunction material act as both an absorber and as an acceptor material. The group IV nanocrystals due to their size (e.g., 50 nm or less, 20 nm or less, 10 nm or less, 5 nm or less) absorb light having a wavelength between about 650 nm and 1000 nm (e.g., a band gap energy of about 1.4 eV to about 1.9 eV). In response to long wavelength light interaction (e.g., 650 nm to 1000 nm), the group IV nanocrystals generate excitons. Both the excitons generated by the organic polymer and the nanocrystals dissociate at the interface between these two materials, thereby producing free electrons and holes. These charges are then transported to the electrodes of a solar cell through a combination of drift and diffusion mechanisms. For example, the free electrons are transported to the solar cell's cathode by hopping between group IV nanocrystals, whereas the holes are transported to the solar cell's anode by hopping between polymer segments.

When positioned between a cathode and an anode, the improved bulk heterojunction material can absorb light from a broader range of wavelengths than known organic heterojunction materials. As a result, the improved bulk heterojunction material made in accordance with the invention will be able to generate more excitons when exposed to sunlight and thus will be more efficient than conventional organic solar cell materials. Moreover, since more excitons are generated, there is a higher probability that free electrons and holes will be collected at their respective electrodes before recombining within the bulk heterojunction material.

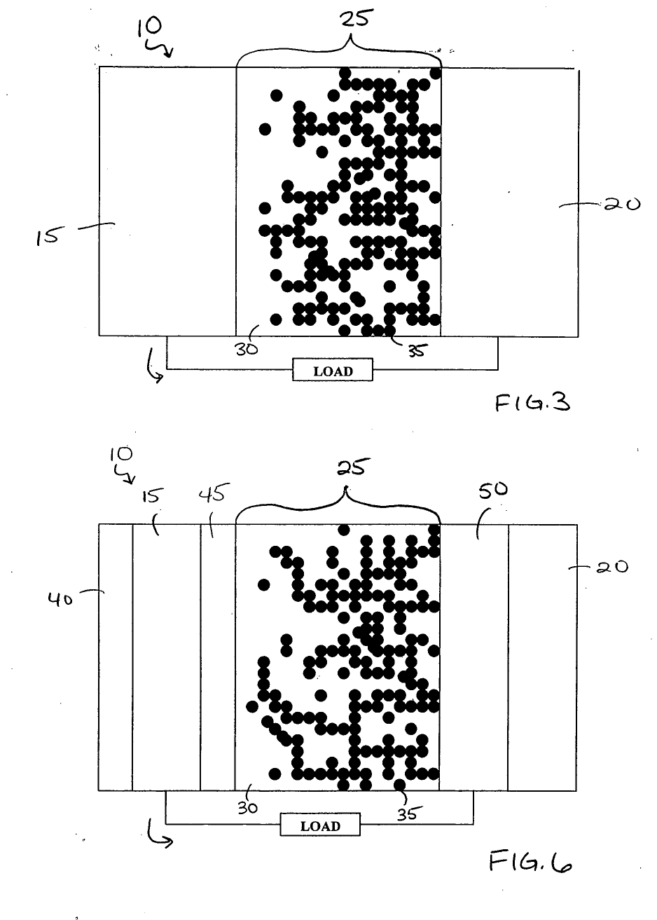

Referring to FIG. 3, in accordance with the present invention, an organic solar cell 10 includes a transparent anode 15, a cathode 20, and a bulk heterojunction material 25 disposed between the anode 15 and the cathode 20. The bulk heterojunction material 25 is formed of a combination of an organic absorber 30 and group IV nanocrystals 35.

In general, the organic absorber 30 is an organic charge conductor that can be made from polymers, dendrimer polymers, or macromers. To date, these materials typically have a band gap value between about 1.9 eV and about 3.5 eV and can efficiently absorb and emit excitons when exposed to light having a wavelength between about 350 nm to about 650 nm. In some embodiments, the organic absorber can have a band gap value of about 1.75 eV to about 1.9 eV. Examples of organic polymers include poly (e-hexylthiophene), poly-[2-methoxy, 5-(2′-ethyl-hexyloxy) phenylene vinylene], and poly(2-methoxy-5-(3′,7′-dimethyloctyloxy)-1,4-phenylene-vinylene). The band gap energy for the proceeding polymers are as follows: about 1.9 eV for poly (e-hexylthiophene), about 2.1 eV for poly-[2-methoxy, 5-(2′-ethyl-hexyloxy) phenylene vinylene], and about 2.3 eV for poly(2-methoxy-5-(3′,7′-dimethyloctyloxy)-1,4-phenylene-vinylene).

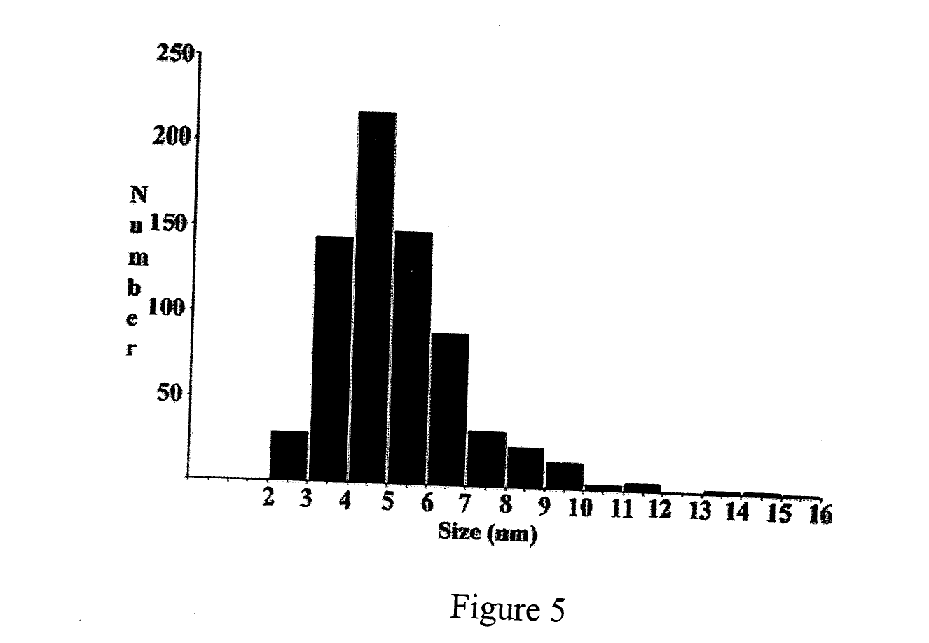

The group IV nanocrystals 35 used to form the heterojunction material 25 are nanosized crystalline particles of group IV elements (e.g., silicon, germanium, tin, carbon, lead, and alloys of group IV elements such as silicon-germanium). In general, at least a portion of the nanocrystals are sized to achieve a band gap of 1.7 eV or more. Without being bound by theory, it is believed that for nanocrystals, the band gap value for an element is related to particle size. That is, that the band gap value is shifted upwards as a result of quantum size effects. For example, investigators have shown that silicon nanocrystals having a maximum dimension of about 3 to 5 nm have a band gap value of about 1.9 eV (whereas bulk crystalline silicon has a band gap value of 1.12 eV at room temperature). As a result of quantum size effects, crystallites of group IV elements having a maximum dimension of 50 nanometers or less (preferably about 20 nanometers or less) have a larger band gap energy than their bulk crystalline counterparts. In addition to the shift in band gap value, group IV nanocrystals also appear to have higher absorption coefficients than do their bulk counterparts. As a result, group IV nanocrystals absorb more light than their bulk counterparts. The present invention utilizes these quantum size effects to broaden the range of wavelengths absorbed from the visible and infrared regions by the bulk heterojunction material. In fact, in some embodiments, the bulk heterojunction material can include group IV nanocrystals of a variety of sizes (e.g., particles having a maximum diameter between about 2 nm about 20 nm), so as to take full advantage of quantum size effects. That is, the nanocrystals within the bulk heterojunction material have a size distribution, such as the size distribution shown in FIG. 5, so as to further broaden the absorption wavelength range (e.g., the smaller particles, such as the 2 nm to 5 nm particles have a band gap energy of about 1.9 eV, whereas the larger particles between about 6 nm and 10 nm have a band gap energy of about 1.7 eV and the particles between about 10 nm and 15 nm have a band gap energy of about 1.5 eV).

Group IV nanocrystals can be produced using any known method or technique. For example, Yang et al. in the Journal of American Chemical Society, volume 121, pages 5191-5195 (1999) describe a method of making alkyl-terminated silicon nanocrystals from a reaction between SiCl₄ and Mg₂Si in ethylene glycol dimethyl ether. Kauzlarich et al. describe a method of making group IV nanocrystals (undoped, and doped N and P-type) with chemically accessible surfaces in high yield in U.S. patent application publication number US2003/0131786, herein incorporated by reference in its entirety. In another related application, Kauzlarich et al. describe a method of making germanium nanocrystals and doped group IV nanocrystals. See, U.S. patent application Ser. No. 10/900,965, filed on Jul. 28, 2004, herein incorporated by reference in its entirety. The methods discussed in both references by Kauzlarich et al. involve producing group IV nanocrystals by contacting a group IV halide and a first reducing agent in a first organic solvent to produce a halide-terminated group IV nanocrystals followed by contacting the halide terminated group IV nanocrystal and a second reducing agent along with a preselected termination group in a second organic solvent to produce group IV nanocrystals terminated with the preselected termination group. The preselected termination groups included, for example, alkyl termination groups, alkoxide termination groups, amino termination groups, butyl termination groups, and hydride termination groups.

The following chart illustrates some of the possible two-step reactions used to generate group IV nanocrystals using the Kaulzarich process:

| | React | To Form | React | To Form |
|---|---|---|---|---|
| Exam- | SiCl₄ | Chloride | Chloride terminated | Alkoxide |
| ple 1 | with Na | terminated Si | Si nanocrystal with | terminated Si |
| | naphtalenide | nanocrystal | 1-octanol | nanocrystals |
| Exam- | GeCl₄ with | Chloride | Chloride terminated | Butyl |
| ple 2 | finely | terminated | Ge nanocrystals | terminated |
| | divided Mg | Ge nano- | with a solution of | Ge nano- |
| | in diglyme | crystals | BuMgCl in | crystals |
| | | | tetrahydrofuran | |
| Exam- | SiCl₄ and | Chloride | Chloride terminated | Butyl |
| ple 3 | GeCl₄ | terminated | SeGe nanocrystals | terminated |
| | with finely | SiGe | with a solution of | Si—Ge |
| | divided Mg | nanocrystals | BuMgCl in | nanocrystals |
| | in diglyme | | tetrahydrofuran | |

The Kaulzarich process described above has several advantages over other nanocrystalline synthesis methods. One of the advantages of this process is that the group IV nanocrystals can be produced in high yield at room temperature and pressure. As a result, group IV nanocrystals can be produced reliably and inexpensively using this method.

Another advantage of this process is that it can produce group IV nanocrystals that can be easily capped with a number of different termination groups (i.e., the group IV-halide bond can be easily replaced with group IV-other element bonds). The group IV nanocrystals can be capped with reagents, such as alky lithiums or grignards to give alkyl terminated nanocrystals or with alcohols to give alkoxide terminated nanocrystals. These capping agents can prevent air and moisture oxidation of the group IV nanocrystals, thereby providing stability to the nanocrystals. The group IV nanocrystals can also be capped with reagents such as electroactive chelating agents, such as, for example, carboxylic acid, heterocyclic aromatic molecules, such as, for example pyridine, and dendrimer polymers. These capping agents can promote wetting between the organic absorber and the group IV nanocrystal. Many other types of terminating groups may be used as well, thus allowing for the possibility of a capping agent that is soluble in a particular organic absorber. There is much literature demonstrating that essentially nucleophilic substitution reactions can be used to replace one cap with another. Therefore, caps can be tailored for a variety of properties, such as protecting the particle from oxidation and/or providing a means of electrical conduction.

The above process can also be used to form doped group IV nanocrystals. For example, Kaulzarich et al., describes a process to produce phosphorus doped silicon nanocrystals by mixing silicon tetrachloride and phosphorus trichloride in dimethoxyethane in the presence of a suspension of a finely divided alkali metal catalyst.

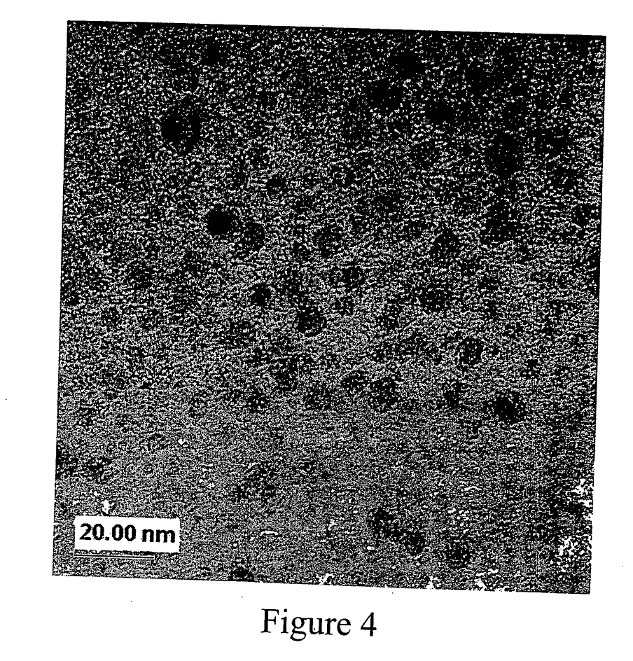

A further advantage of the Kaulzarich process is that it allows for control over the size and morphology of the nanocrystals produced. For example, the size of the nanocrystals produced appears to be proportional to reaction times. Specifically, Kaulzarich et al. report that longer reaction times lead to larger particles sizes (e.g., about 50 nm), whereas short reaction times (e.g., on the order of hours) lead to nanocrystals having smaller sizes (e.g., 10 nm or less). As a result of this high level of size control, the Kaulzarich process can be used to form group IV nanocrystals having a maximum dimension of 20 nm or less (see FIG. 4) and a particle size distribution as shown in FIG. 5.

The organic absorber 30 and the group IV nanocrystals 35 can be mixed together using any known means to form an interpercolating network between the organic absorber 30 and the nanocrystals 35 (e.g., the group IV nanocrystals are immersed within the organic polymer). In general, the organic absorber 30 and the group IV nanocrystals are mixed together so as to produce a large number of interfaces between the polymer and the nanocrystals (i.e., a high degree of mixing) where excitons can dissociate, while still maintaining a critical phase separation threshold so that dissociated exciton charge carriers can be efficiently transported to their respective electrode before recombination occurs. In some embodiments, the interpercolating network is formed by a mixture of 75 weight percent of group IV nanocrystals to 25 weight percent organic polymer. In other embodiments, the interpercolating network is formed by a mixture of 70 weight percent of group IV nanocrystals to 30 weight percent organic polymer. In still other embodiments, the interpercolating network is formed by a mixture of 70 to 50 weight percent of group IV nanocrystals and 30 to 50 weight percent of organic polymer.

In general, the electrodes of the organic solar cell 10 (i.e., the anode 15 and the cathode 20) are formed from materials having differing conductive characteristics. For example, the anode 15 is typically formed from a high work function material, such as, for example indium tin oxide (ITO) and the cathode 20 is generally formed of a low work function material, such as aluminum, calcium, or magnesium. The difference in work function between the anode 15 and the cathode 20 provides an electric field, which drives the separated charge carriers (i.e., holes and electrons) towards their respective electrodes.

In the embodiment shown in FIG. 3, the anode 15 is made from a transparent (e.g., at least semi-transparent) material, ITO, so that sunlight can pass through the anode 15 and interact with the heterojunction material 25. In some embodiments, not shown, the cathode 20 can also be made from or include a transparent or semi-transparent material so that light can be absorbed from both the anode side and the cathode side of the organic solar cell.

Referring to FIG. 6, in some embodiments, the organic solar cell 10 can include buffer layers and/or substrates to improve the efficiency and/or stability of the solar cell. For example, in some embodiments, the anode 15 can include a substrate 40, such as a transparent or semi-transparent glass or plastic substrate, to support the ITO anode. The anode 15 can further include an anode buffer layer 45, such as a layer of PEDOT which can increase the ITO work function and create a smoother electrode surface. Likewise, the cathode 20 can further include a cathode buffer layer 50, such as a layer of LiF, to enhance the fill factor and to stabilize high open circuit voltages within the cell.

In general, the bulk heterojunction material 25 can be disposed on one of the two electrodes using wet-processing techniques, such as spin casting, dip coating, ink jet printing, screen printing, and micromolding. These techniques are highly attractive for producing large-area solar cells inexpensively because they can be performed at ambient temperatures and pressures and are easily scalable to large manufacturing production with little material loss.

In general, the bulk heterojunction material 25 is deposited using a wet-processing technique to have a thickness that limits the amount of recombination of holes and electrons within the bulk heterojunction material. For example, in some embodiments, the bulk heterojunction material 25 is deposited using any of the above techniques to have a thickness between about 75 nm to about 200 nm. In certain embodiments, the heterojunction material is deposited using any of the above techniques to have a thickness between about 100 nm to about 150 nm.

In general, in some embodiments, the organic absorber 30 is formed from a p-type doped organic polymer. As a result, at least a portion (e.g., 25%, 50%, 75%) of the group IV nanocrystals are doped n-type. Moreover, each of the n-type doped group IV nanocrystals can have a different level or degree of doping (e.g, some nanocrystals can be lightly or undoped while other nanocrystals are heavily doped).

In some embodiments, the bulk heterojunction material includes both n-type and p-type doped group IV nanocrystals. For example, near the anode 15, the heterojunction material can include heavily doped p-type silicon nanocrystals; while near the cathode 20, the heterojunction material can include heavily doped n-type silicon nanocrystals.

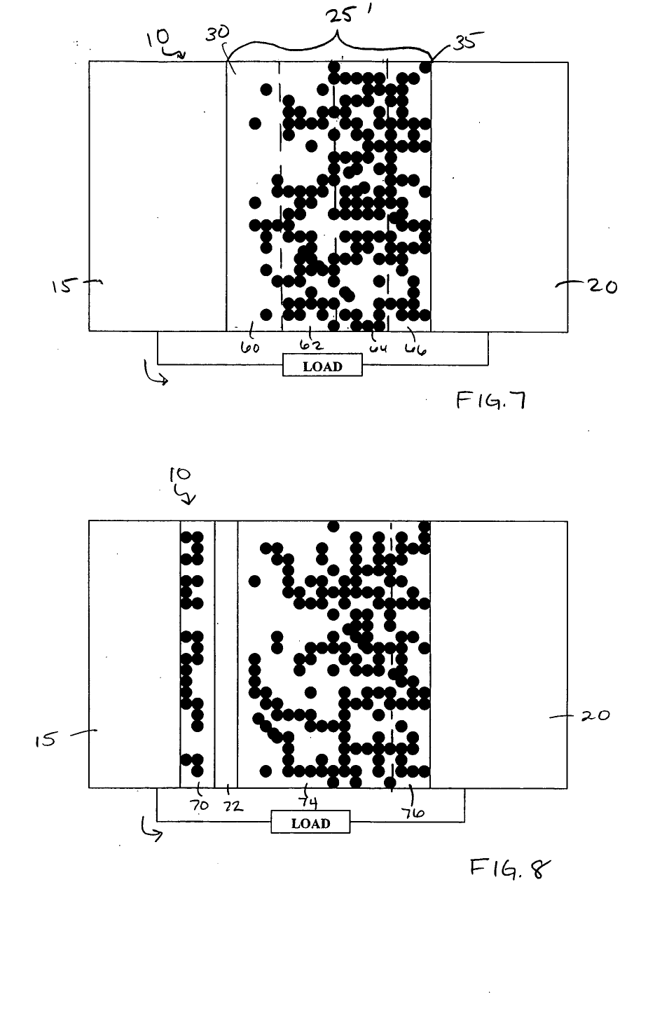

In some embodiments, the bulk heterojunction material can be deposited on the electrodes of the solar cell to include a number of layers or regions (e.g., 2 layers, 3 layers, 4 layers, 5 layers, 6 layers, 7 layers) in which doping levels vary therebetween. For example, referring to FIG. 7, the bulk heterojunction material 25′ includes four layers labeled 60, 62, 64, and 66. In each of these layers the doping level and/or type differs. Layer 60, which is closest to anode 15 is heavily doped p-type (e.g., between 10¹⁹ to 10²⁰ atoms/cm³ or more) and layer 66, which is closest to the cathode 20, is heavily doped n-type (e.g., between about 10¹⁹ to 10²⁰ atoms/cm³). Layers 62 and 64, which form the center portion of the solar cell 10, are either lightly doped either n-type or p-type (e.g., between about 10¹⁶ to 10¹⁸ atoms/cm³ or less) or undoped. FIG. 8 shows another layered embodiment, in which layer 70 includes heavily doped p-type group IV nanocrystals immersed within an organic polymer, layer 72 includes the organic polymer, layer 74 includes lightly n-type doped group IV nanocrystals, and layer 76 includes heavily n-type doped group IV nanocrystals. As a result of these layering schemes (e.g., the layers closest to the electrodes are more heavily doped than the layers closest to the center of the solar cell) contacts to external electrodes and between adjacent solar cells are improved while internal recombination is minimized.

The layered bulk heterojunction material 25′ can be produced, for example, using an inkjet processing technique in which layers 60, 62, 64, and 66 are deposited sequentially. Some mixing of the layers 60, 62, 64, and 66 can occur about their interfaces. However, due to slow diffusion rates, layers 60, 62, 64, and 66 do not substantially blend together, but rather remain distinct from each other.

Once the bulk heterojunction material 25 has been deposited on an electrode, the opposing electrode is then positioned on top of the bulk heterojunction material to complete the solar cell 10. Two or more organic solar cells 10 can be joined together in series or parallel in accordance with known methods to form solar cell modules.

Variations, modifications, and other implementations of what is described herein will occur to those of ordinary skill without departing from the spirit and the scope of the invention. Accordingly, the invention is not to be defined only by the preceding illustrative description.

1. A solar cell comprising:
a cathode;
an anode;
a bulk heterojunction material disposed between the cathode and the anode, the buk heterojunction material comprising a combination of an organic absorber and a plurality of group IV nanocrystals,
wherein at least one of the cathode and the anode is at least semi-transparent.

2. The solar cell of claim 1, wherein the plurality of group IV nanocrystals comprises less than about 75 weight percent of the bulk heterojunction material.

3. The solar cell of claim 2, wherein the plurality of group IV nanocrystals comprises between about 50 weight percent and 70 weight percent of the bulk heterojunction material.

4. The solar cell of claim 1, wherein the plurality of group IV nanocrystals include a variety of particle sizes.

5. The solar cell of claim 4, wherein each of the plurality of group IV nanocrystals has a largest particle dimension which is less than about 20 nanometers.

6. The solar cell of claim 4, wherein a portion of the plurality of the group IV nanocrystals have a largest particle dimension within the range of about 2 nanometers to about 5 nanometers.

7. The solar cell of claim 1, wherein the plurality of group IV nanocrystals comprise silicon nanocrystals.

8. The solar cell of claim 1, wherein the plurality of group IV nanocrystals comprise germanium nanocrystals.

9. The solar cell of claim 1, wherein the plurality of group IV nanocrystals comprise silicon-germanium nanocrystals.

10. The solar cell of claim 1, wherein at least a portion of the plurality of group IV nanocrystals are doped.

11. The solar cell of claim 10, wherein group IV nanocrystals located near the cathode and anode are more heavily doped than the group IV nanocrystals located near a center position of the solar cell.

12. The solar cell of claim 1, wherein the bulk heterojunction material further comprises a heavily n-type doped region located near the cathode, a heavily p-type doped region located near the anode, and a lightly doped region located therebetween.

13. The solar cell of claim 1, wherein at least a portion of the plurality of group IV nanocrystals are capped with a reagent.

14. The solar cell of claim 13, wherein the reagent is selected from the group consisting of alkyl lithium, a grignard, or an alcohol.

15. The solar cell of claim 13, wherein the reagent is selected from the group consisting of an electroactive chelating agent, a heterocyclic aromatic molecule, and a dendrimer polymer.

16. The solar cell of claim 1, wherein the organic absorber comprises a polymer, a dendrimer, or a macromer.

17. The solar cell of claim 1, wherein the organic absorber is selected from the group consisting of poly (e-hexylthiophene), poly-[2-methoxy, 5-(2′-ethyl-hexyloxy) phenylene vinylene], and poly(2-methoxy-5-(3′,7′-dimethyloctyloxy)-1,4-phenylene-vinylene).

18. A bulk heterojunction material comprising:
an organic absorber; and
a plurality of group IV nanocrystals disposed within the organic absorber.

19. The bulk heterojunction material of claim 18, wherein the plurality of group IV nanocrystals comprises less than about 75 weight percent of the bulk heterojunction material.

20. The bulk heterojunction material of claim 19, wherein the plurality of group IV nanocrystals comprises between about 50 weight percent and 70 weight percent of the bulk heterojunction material.

21. The bulk heterojunction material of claim 18, wherein the plurality of group IV nanocrystals include a variety of particle sizes.

22. The bulk heterojunction material of claim 21, wherein each of the plurality of group IV nanocrystals has a largest particle dimension which is less than about 20 nanometers.

23. The bulk heterojunction material of claim 21, wherein a portion of the plurality of the group IV nanocrystals have a largest particle dimension within the range of about 2 nanometers to about 5 nanometers.

24. The bulk heterojunction material of claim 18, wherein the plurality of group IV nanocrystals comprise silicon nanocrystals.

25. The bulk heterojunction material of claim 18, wherein the plurality of group IV nanocrystals comprise germanium nanocrystals.

26. The bulk heterojunction material of claim 18, wherein the plurality of group IV nanocrystals comprise silicon-germanium nanocrystals.

27. The bulk heterojunction material of claim 18, wherein at least a portion of the plurality of group IV nanocrystals are doped.

28. The bulk heterojunction material of claim 18, wherein at least a portion of the plurality of group IV nanocrystals are capped with a reagent.

29. The bulk heterojunction material of claim 28, wherein the reagent is selected from the group consisting of alkyl lithium, a grignard, or an alcohol.

30. The bulk heterojunction material of claim 28, wherein the reagent is selected from the group consisting of an electroactive chelating agent, a heterocyclic aromatic molecule, and a dendrimer polymer.

31. The bulk heterojunction material of claim 18, wherein the organic absorber comprises a polymer, a dendrimer, or a macromer.

32. The bulk heterojunction material of claim 18, wherein the organic absorber is selected from the group consisting of poly (e-hexylthiophene), poly-[2-methoxy, 5-(2′-ethyl-hexyloxy) phenylene vinylene], and poly(2-methoxy-5-(3′,7′-dimethyloctyloxy)-1,4-phenylene-vinylene).

33. A method of forming a bulk heterojunction material, the method comprising:
immersing a plurality of group IV nanocrystals in an organic absorber.

34. The method of claim 33 further comprising capping at least a portion of the plurality of group IV nanocrystals with a reagent.

35. The method of claim 33 further comprising doping at least a portion of the plurality of group IV nanocrystals.

36. The method of claim 33, wherein the plurality of group IV nanocrystals include a variety of particle sizes.

37. The method of claim 33, wherein a portion of the plurality of group IV nanocrystals have a largest dimension within the range of about 2 nanometers to about 5 nanometers.

38. The method of claim 33, wherein the plurality of group IV nanocrystals comprises silicon nanocrystals.

39. The method of claim 33, wherein the plurality of group IV nanocrystals comprises germanium nanocrystals.

40. The method of claim 33, wherein the plurality of group IV nanocrystals comprises silicon-germanium nanocrystals.

41. A method of forming a solar cell, the method comprising:
depositing a layer of a bulk heterojunction material on to a first electrode having a first work function; and
positioning a second electrode having a second work function, which differs from the first work function, on top of the layer of bulk heterojunction material,
wherein the bulk heterojunction material comprises a combination of an organic absorber and a plurality of group IV nanocrystals.

42. The method of claim 41, wherein depositing a layer of a bulk heterojunction material comprises depositing a 75 nm to 200 nm thick layer of the bulk heterojunction material.

43. The method of claim 41, wherein the plurality of group IV nanocrytals comprises less than about 75 weight percent of the heterojunction material.

44. The method of claim 41, wherein the plurality of group IV nanocrystals include a variety of particle sizes.

45. The method of claim 41, wherein each of the plurality of group IV nanocrystals has a largest particle dimension which is less than about 20 nanometers.

46. The method of claim 41, wherein the plurality of group IV nanocrystals comprise silicon nanocrystals.

47. The method of claim 41, wherein the plurality of group IV nanocrystals comprise germanium nanocrystals.

48. The method of claim 41, wherein the plurality of group IV nanocrystals comprise silicon-germanium nanocrystals.

49. The method of claim 41, wherein at least a portion of the plurality of group IV nanocrystals are doped.

50. The method of claim 49, wherein group IV nanocrystals located near the first electrode and the second electrode are more heavily doped than the group IV nanocrystals located near a center position of the solar cell.

51. The method of claim 41, wherein the bulk heterojunction material further comprises heavily doped regions located near the first and second electrodes and a lightly doped region located therebetween.

52. The method of claim 41, wherein at least a portion of the plurality of group IV nanocrystals are capped with a reagent.

53. The method of claim 52 wherein the reagent is selected from the group consisting of alkyl lithium, a grignard, or an alcohol.

54. The method of claim 52, wherein the reagent is selected from the group consisting of an electroactive chelating agent, a heterocyclic aromatic molecule, and a dendrimer polymer.

55. The method of claim 41, wherein the organic absorber comprises a polymer, a dendrimer, or a macromer.

56. The method of claim 41, wherein the organic absorber is selected from the group consisting of poly (e-hexylthiophene), poly-[2-methoxy, 5-(2′-ethyl-hexyloxy) phenylene vinylene], and poly(2-methoxy-5-(3′,7′-dimethyloctyloxy)-1,4-phenylene-vinylene).

57. The method of claim 41, wherein at least one of the first electrode and the second electrode is substantially transparent.
